(19) United States
(12) Patent Application Publication
(10) Pub. No.: US 2003/0151098 A1
(43) Pub. Date: Aug. 14, 2003

(54) Semiconductor device having dual-gate structure and method of manufacturing the same

(75) Inventors: Yukio Nishida, Tokyo (JP); Katsuyuki Horita, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/214,593

(22) Filed: Aug. 9, 2002

(30) Foreign Application Priority Data
Feb. 13, 2002 (JP) 2002-035084

(51) Int. Cl. H01L 29/76; H01L 31/062

(52) U.S. Cl. 257/369; 257/374; 257/388; 257/410; 257/412; 257/413

(57) ABSTRACT

By forming a doped polysilicon layer (PS2) containing boron through the CVD method in a material gas including a compound containing boron such as BCl₃ (boron trichloride), an opening left after removing a gate electrode (11) in a region (PR) is filled with the doped polysilicon layer (PS2). In the doped polysilicon layer (PS2), boron atoms are uniformly distributed with high activation rate. Thus provided is a method of manufacturing a semiconductor device, which is capable of suppressing depletion of a gate electrode of a P-channel MOS transistor and suppressing penetration of impurity in a CMOS transistor of dual-gate structure.

### BACKGROUND OF THE INVENTION

1. Field of the Invention

The present invention relates to a semiconductor device, and more particularly to a semiconductor device having a dual-gate structure.

2. Description of the Background Art

In manufacturing a semiconductor integrated circuit, it is advantageous to use a CMOS (Complementary MOS) transistor for reducing power consumption and ensuring a larger operational margin, and the CMOS transistor is widely used at present. The CMOS transistors are broadly divided into those of single-gate structure and those of dual-gate structure.

The single-gate structure is a structure in which gate electrodes of an N-channel MOS transistor and a P-channel MOS transistor constituting a CMOS transistor are each formed of polysilicon and have an N-type impurity. In general, phosphorus is introduced therein as the N-type impurity.

Since the phosphorus of the gate electrode is introduced, being contained in a gas when a gate polysilicon layer is formed, the phosphorus in the gate polysilicon layer is permeated overall and distributed in almost uniform concentration. Such a polysilicon layer containing an impurity is generally referred to as a doped polysilicon layer. In the present description, the impurity polysilicon layer formed in such a way is referred to as a doped polysilicon layer.

On the other hand, in the dual-gate structure, a polysilicon gate containing an N-type impurity is used for the N-channel MOS transistor and a polysilicon gate containing a P-type impurity is used for the P-channel MOS transistor.

Usually, in forming the dual-gate structure, no impurity is introduced when a gate polysilicon layer is formed by the CVD (Chemical Vapor Deposition) method and after that, an N-type impurity is implanted by ion implantation into the gate electrode of the N-channel MOS transistor and a P-type impurity is implanted by ion implantation into the gate electrode of the P-channel MOS transistor.

The single-gate structure and the dual-gate structure have respective advantages and disadvantages.

<Single-Gate Structure in the Background Art>

FIG. 16 is a cross section showing a CMOS transistor of general single-gate structure, which includes an N-channel MOS transistor 100 and a P-channel MOS transistor 200.

The N-channel MOS transistor 100 has a gate insulating film 102 selectively provided on a main surface of a silicon substrate 1, a gate electrode 101 provided on the gate insulating film 102, sidewall insulating films 103 provided on side surfaces of the gate electrode 101 and the gate insulating film 102, a pair of source/drain layers 104 provided in the main surface of the silicon substrate 1 positioned on external portions of the side surfaces of the gate electrode 101, being spaced out and opposed to each other, and a pair of extension layers 105 extending from facing end portions of the pair of source/drain layers 104 towards each other. Further, the gate electrode 101 contains an N-type impurity therein.

In the N-channel MOS transistor 100, a channel is formed in the surface of the silicon substrate 1 positioned between the pair of extension layers 105 below the gate insulating film 102, and therefore this is referred to as a transistor of surface channel structure (hereafter, referred to as “SC structure”).

A source/drain extension layer is an impurity layer which is so formed as to make a junction shallower than that of the source/drain layer, having the same conductivity type as the source/drain main layer. Though this is referred to as “source/drain extension layer” since it has a function as a source/drain layer, the layer is referred to simply as “extension layer” in the discussion of the present invention for convenience.

The P-channel MOS transistor 200 has a gate insulating film 202 selectively provided on the main surface of the silicon substrate 1, a gate electrode 201 provided on the gate insulating film 202, sidewall insulating films 203 provided on side surfaces of the gate electrode 201 and the gate insulating film 202, a pair of source/drain layers 204 provided in the main surface of the silicon substrate 1 positioned on external portions of the side surfaces of the gate electrode 201, being spaced out and opposed to each other, and a buried layer 206 provided in the main surface of the silicon substrate 1 positioned between the pair of the source/drain layers 204. Further, the gate electrode 201 contains an N-type impurity therein.

The buried layer 206 contains a P-type impurity of low concentration and the P-channel MOS transistor 200 is referred to as a transistor of buried channel structure (hereafter, referred to as “BC structure”).

Respective formation regions of the N-channel MOS transistor 100 and the P-channel MOS transistor 200 are separated by an isolation oxide film 2 provided in the main surface of the silicon substrate 1.

Thus, the reason why the P-channel MOS transistor 200 has a BC structure is that both the gate electrodes 101 and 201 contain the N-type impurity, in other words, this transistor is a CMOS transistor of single-gate structure.

With such a BC structure, it is possible to reduce the threshold value even if the gate electrode 201 of the P-channel MOS transistor 200 contains the N-type impurity. The BC structure, however, is hard to miniaturize and causes a difficulty in size reduction of transistors for high integration.

Further, there is a possible case as a single-gate structure, opposite to the case of FIG. 16, where the gate electrodes of the N-channel MOS transistor and the P-channel MOS transistor contain the P-type impurity. In such a case, however, since the N-channel MOS transistor has a BC structure though the P-channel MOS transistor has a SC structure, there similarly arises a difficulty in miniaturization.

Furthermore, when boron (B) is introduced as the P-type impurity for forming a gate polysilicon layer, there is a great possibility that the boron is moved from the gate electrode to the silicon substrate through the gate insulating film, in other words, penetration of boron is caused, by the later heat treatment such as annealing for forming the source/drain layers. The penetration of boron causes variation in threshold values (Vth) of the P-channel MOS transistor.

<Dual-Gate Structure in the Background Art>

FIG. 17 is a cross section showing a CMOS transistor of general dual-gate structure, which includes an N-channel MOS transistor 300 and a P-channel MOS transistor 400.

The N-channel MOS transistor 300 has a gate insulating film 302 selectively provided on the main surface of the silicon substrate 1, a gate electrode 301 provided on the gate insulating film 302, sidewall insulating films 303 provided on side surfaces of the gate electrode 301 and the gate insulating film 302, a pair of source/drain layers 304 provided in the main surface of the silicon substrate 1 positioned on external portions of the side surfaces of the gate electrode 301, being spaced out and opposed to each other, and a pair of extension layers 305 extending from facing end portions of the pair of source/drain layers 304 towards each other. Further, the gate electrode 301 contains an N-type impurity therein.

In the N-channel MOS transistor 300, a channel is formed in the surface of the silicon substrate 1 positioned between the pair of extension layers 305 below the gate insulating film 302, and therefore this is referred to as a transistor of SC structure.

The P-channel MOS transistor 400 has a gate insulating film 402 selectively provided on the main surface of the silicon substrate 1, a gate electrode 401 provided on the gate insulating film 402, sidewall insulating films 403 provided on side surfaces of the gate electrode 401 and the gate insulating film 402, a pair of source/drain layers 404 provided in the main surface of the silicon substrate 1 positioned on external portions of the side surfaces of the gate electrode 401, being spaced out and opposed to each other, and a pair of extension layers 405 extending from facing end portions of the pair of source/drain layers 404 towards each other. Further, the gate electrode 401 contains a P-type impurity therein.

Respective formation regions of the N-channel MOS transistor 300 and the P-channel MOS transistor 400 are separated by the isolation oxide film 2 provided in the main surface of the silicon substrate 1.

Thus, the N-channel MOS transistor 300 and the P-channel MOS transistor 400 each have a SC structure and this produces an advantage in miniaturization.

The dual-gate structure, however, has a problem of depletion of the gate electrode. Specifically, the concentration of impurity atoms introduced in the gate polysilicon layer by ion implantation is not uniform and a bottom portion of the gate electrode (on the side of the gate insulating film) has lower concentration. It is difficult, in particular, to efficiently activate the ion-implanted boron atoms in the gate electrode of the P-channel MOS transistor. Therefore, in the CMOS transistor of dual-gate structure, a relatively thick depletion layer is produced in the gate electrode of the P-channel MOS transistor. Since the depletion layer works like the gate insulating film, producing the depletion layer actually corresponds to thickening the gate insulating film and this deteriorates the capability of the P-channel MOS transistor to drive drain currents.

Among methods to prevent depletion of the gate electrode are increasing the amount of boron atoms to be ion-implanted into the gate or performing the annealing at higher temperature to raise the activation rate of the boron. These methods, however, leads to accelerating the above penetration of boron. Therefore, as to the CMOS transistor of dual-gate structure, it is a great challenge to suppress both the depletion and the penetration in the P-channel MOS transistor.

As discussed above, it is preferable to form both the N-channel MOS transistor and the P-channel MOS transistor of SC structure for miniaturization of a semiconductor device, in other words, adopt the dual-gate structure, but in order to achieve the dual-gate structure, conventionally, an impurity is introduced into at least one gate electrode by ion implantation. Then, when boron is introduced into the gate electrode of the P-channel MOS transistor by ion implantation, this causes a problem of depletion and when the amount of boron to be implanted is increased or the heat treatment is performed at higher temperature in order to solve this problem, the penetration of boron is likely to occur since the boron is an atom which is relatively easy to diffuse.

### SUMMARY OF THE INVENTION

It is an object of the present invention to provide a method of manufacturing a semiconductor device, which is capable of suppressing depletion of a gate electrode of a P-channel MOS transistor and suppressing penetration of impurity in a CMOS transistor of dual-gate structure.

According to a first aspect of the present invention, the semiconductor device includes an N-channel MOS transistor and a P-channel MOS transistor which are provided on the semiconductor substrate. The N-channel MOS transistor has a first gate insulating film selectively provided on a surface of the semiconductor substrate, and a first gate electrode provided on the first gate insulating film. The P-channel MOS transistor has a second gate insulating film selectively provided on the surface of the semiconductor substrate, and a second gate electrode provided on the second gate insulating film. The first gate electrode is formed of a first doped polysilicon layer containing an N-type impurity therein, and the second gate electrode is formed of a second doped polysilicon layer containing a P-type impurity therein.

Since the first gate electrode which is a constituent of the N-channel MOS transistor is formed of the first doped polysilicon layer containing the N-type impurity therein and the second gate electrode which is a constituent of the P-channel MOS transistor is formed of the second doped polysilicon layer containing the P-type impurity therein, it is possible to provide a CMOS transistor of dual-gate structure in which these two MOS transistors are each of surface channel structure and it becomes easier to manufacture the MOS transistor which can respond to miniaturization. Further, since the first and second gate electrodes contains the N-type impurity and the P-type impurity, respectively, it is possible to suppress depletion of the gate electrode and prevent the capability of the P-channel MOS transistor to drive drain currents from being deteriorated by the depletion of the gate electrode.

According to a second aspect of the present invention, the semiconductor device includes an N-channel MOS transistor and a P-channel MOS transistor which are provided on the semiconductor substrate. The N-channel MOS transistor has a first gate insulating film selectively provided on a surface of the semiconductor substrate, and a first gate electrode provided on the first gate insulating film. The P-channel MOS transistor has a second gate insulating film selectively provided on the surface of the semiconductor substrate, and a second gate electrode provided on the second gate insulating film. The first gate electrode is formed of a first doped polysilicon layer containing an N-type impurity therein, and the second gate electrode is formed of at least one metal layer.

Since the first gate electrode which is a constituent of the N-channel MOS transistor is formed of the first doped polysilicon layer containing the N-type impurity therein and the second gate electrode which is a constituent of the P-channel MOS transistor is formed of at least one metal layer, it is possible to completely avoid depletion of the second gate electrode and also reduce the gate resistance thereof. Further, the N-channel MOS transistor can be formed in a surface channel structure.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 7 are cross sections showing a process for manufacturing a semiconductor device in accordance with a first preferred embodiment of the present invention step by step;

FIGS. 8 to 12 are cross sections showing a process for manufacturing a semiconductor device in accordance with a second preferred embodiment of the present invention step by step;

FIGS. 13 to 15 are cross sections showing a process for manufacturing a semiconductor device in accordance with a third preferred embodiment of the present invention step by step;

FIG. 16 is a cross section showing a CMOS transistor of single-gate structure in the background art; and

FIG. 17 is a cross section showing a CMOS transistor of dual-gate structure in the background art.

### DESCRIPTION OF THE PREFERRED EMBODIMENTS

<A. The First Preferred Embodiment>

<A-1. Manufacturing Method>

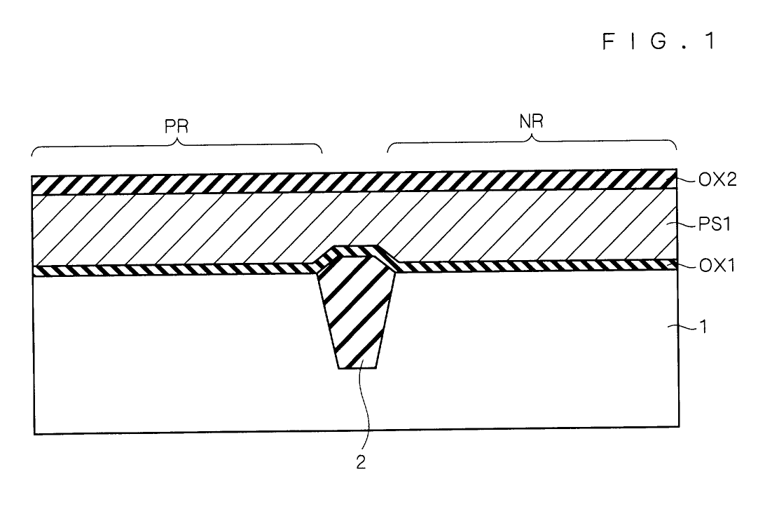

A method of manufacturing a semiconductor device in accordance with the first preferred embodiment of the present invention will be discussed, referring to the cross sections of FIGS. 1 to 5 showing the manufacturing process step by step.

First, in the step of FIG. 1, the isolation oxide film 2 is selectively formed in the main surface of the silicon substrate 1, thereby defining regions NR and PR for forming an N-channel MOS transistor and a P-channel MOS transistor, respectively. Then, a P-type impurity is ion-implanted into the region NR and an N-type impurity is ion-implanted into the region PR, to form a well region and a channel implantation region (both not shown).

After that, a silicon oxide film OX1 is so formed as to have a thickness of about 3 nm entirely on the main surface of the silicon substrate 1. This silicon oxide film OX1 becomes a gate insulating film later.

Subsequently, a doped polysilicon layer PS1 is so formed as to have a thickness of about 200 nm on the silicon oxide film OX1 by the CVD method with a material gas including a compound containing phosphorus such as PCl₃ (phosphorus trichloride). In the doped polysilicon layer PS1, phosphorus atoms are uniformly distributed with high activation rate (as compared with a case where the impurity of almost equal concentration is ion-implanted), and this layer is referred to as an N-type doped polysilicon layer in some case hereafter. Further, the doped polysilicon layer PS1 contains the N-type impurity in a concentration range of 5×10¹⁹ to 5×10²⁰/cm³.

After that, a TEOS oxide film OX2 is so formed as to have a thickness of about 80 nm on the doped polysilicon layer PS1 by the CVD method,.

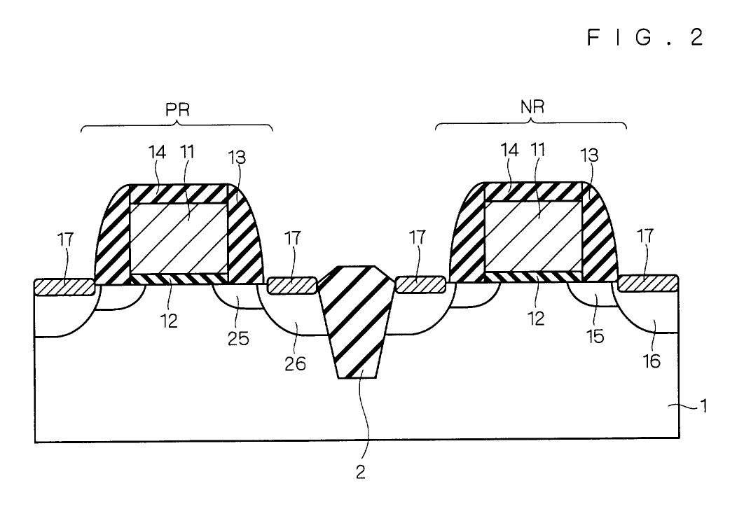

Next, in the step of FIG. 2, a resist mask (not shown) having a plane pattern of gate electrode is formed on the TEOS oxide film OX2 and the TEOS oxide film OX2 is etched using the resist mask. With this etching, the TEOS oxide film OX2 is so patterned as to have the plane pattern of gate electrode.

After that, the doped polysilicon layer PS1 and the silicon oxide film OX1 are patterned by etching with the patterned TEOS oxide film OX2 used as a hardmask, to form first and second gate multi-layered structures each consisting of a gate electrode 11, a gate insulating film 12 and a TEOS oxide film 14 in the regions NR and PR, respectively.

Further, the TEOS oxide film 14 also serves as a protection film for preventing formation of any silicide layer on the gate electrode 11 when the silicide layer is formed on the source/drain layers as discussed later, but if no silicide layer is formed on the source/drain layers, the first and second gate multi-layered structures do not always need to include the TEOS oxide film 14.

Then, the region PR is covered with a resist mask (not shown) and an N-type impurity is implanted into the region NR with the first gate multi-layered structure used as an implantation mask, to so form a pair of extension layers 15 as to be spaced out and opposed to each other in the main surface of the silicon substrate 1 positioned on external portions of side surfaces of the gate electrode 11. Further, the region NR is covered with a resist mask (not shown) and a P-type impurity is implanted into the region PR with the second gate multi-layered structure used as an implantation mask, to so form a pair of extension layers 25 as to be spaced out and opposed to each other in the main surface of the silicon substrate 1 positioned on external portions of side surfaces of the gate electrode 11.

Furthermore, following the formation of the extension layers 15 and 25, pocket layers may be formed by ion implantation, which extends up to a portion immediately below the gate electrode 11 e.g., with the silicon substrate 1 inclined.

The pocket layers provided in the regions NR and PR are formed by implanting impurities having conductivity types opposite to those of the extension layers 15 and 25, respectively, for the purpose of suppressing horizontal extension of the depletion layers from the drain layers to prevent punch through.

Next, a silicon nitride film is so formed by the CVD method entirely on the silicon substrate 1 as to cover the first and second gate multi-layered structures in the regions NR and PR. After that, the silicon nitride film is etched back by anisotropic etching or the like, to form sidewall spacers 13 of silicon nitride film on the side surfaces of the first and second gate multi-layered structures.

After that, the region PR is covered with a resist mask (not shown) and an N-type impurity (e.g., arsenic) is implanted into the region NR with the first gate multi-layered structure and the sidewall spacers 13 used as an implantation mask, to so form a pair of source/drain layers 16 as to be spaced out and opposed to each other in the main surface of the silicon substrate 1 positioned on external portions of side surfaces of the gate electrode 11. Further, the region NR is covered with a resist mask (not shown) and a P-type impurity (e.g., boron) is implanted into the region PR with the second gate multi-layered structure and the sidewall spacers 13 used as an implantation mask, to so form a pair of source/drain layers 26 as to be spaced out and opposed to each other in the main surface of the silicon substrate 1 positioned on external portions of side surfaces of the gate electrode 11. In forming the source/drain layers 16 and 26, an activation annealing is performed after implanting the impurities.

After that, a refractory metal layer such as a cobalt layer is formed, as necessary, by vapor deposition or the like entirely on the main surface of the silicon substrate 1, and a heat treatment is performed on the refractory metal layer, making a silicide reaction between silicon and cobalt, to form silicide layers 17 at contact portions of the silicon surface and the cobalt film. Herein, the silicide layers 17 are formed only on surfaces of the source/drain layers 16 and 26, achieving the structure shown in FIG. 2.

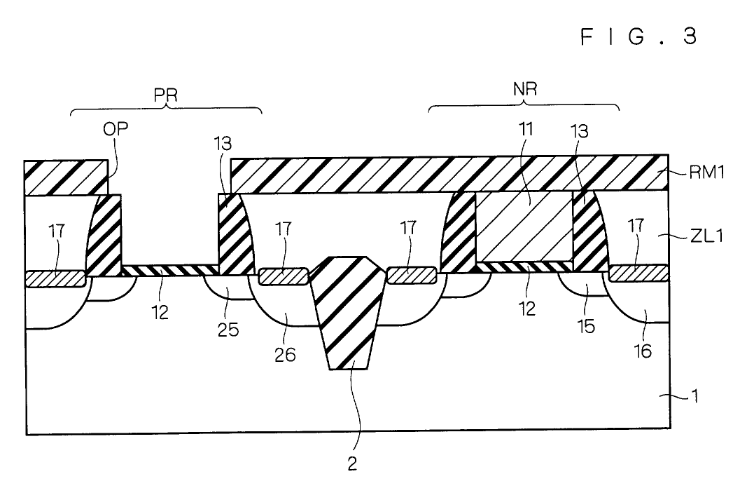

Next, in the step of FIG. 3, an interlayer insulating film ZL1 is so formed as to have a thickness of about 1500 nm on the main surface of the silicon substrate 1, to fully cover the first and second gate multi-layered structures and the sidewall spacers 13. After that, the interlayer insulating film ZL1 is polished by CMP (Chemical Mechanical Polishing) and the whole TEOS oxide film 14 and upper end portions of the sidewall spacers 13 are also polished, to expose an uppermost surface of the gate electrode 11.

Then, an upper portion of the gate electrode 11 in the region PR becomes an opening OP, and using a resist mask RM1 which is so patterned as to cover a portion other than the opening OP, the gate electrode 11 in the region PR is removed by wet etching with a potassium hydroxide solution (KOH) or aqueous ammonia. Thus, since the gate electrode 11 in the region PR is removed, the electrode may be referred to as a dummy gate electrode. If the interlayer insulating film ZL1 is formed of silicon nitride film, it is possible to prevent the interlayer insulating film ZL1 from being removed even when the opening OP of the resist mask RM1 extends over the interlayer insulating film ZL1 in removing the gate electrode 11.

Further, if the interlayer insulating film ZL1 is formed of silicon nitride film, since the silicon nitride film is hard to dissolve even in a mixture of hydrofluoric acid (HF) and nitric acid (HNO₃), the gate electrode 11 in the region PR can be removed with this mixture. In this case, though there is a possibility that the gate insulating film 12 in the region PR may be removed at the same time if the gate insulating film 12 is formed of silicon oxide film, if a new gate insulating film which is not affected by the etching or the like is formed after removing the gate insulating film 12, it is possible to increase reliability of the gate insulating film.

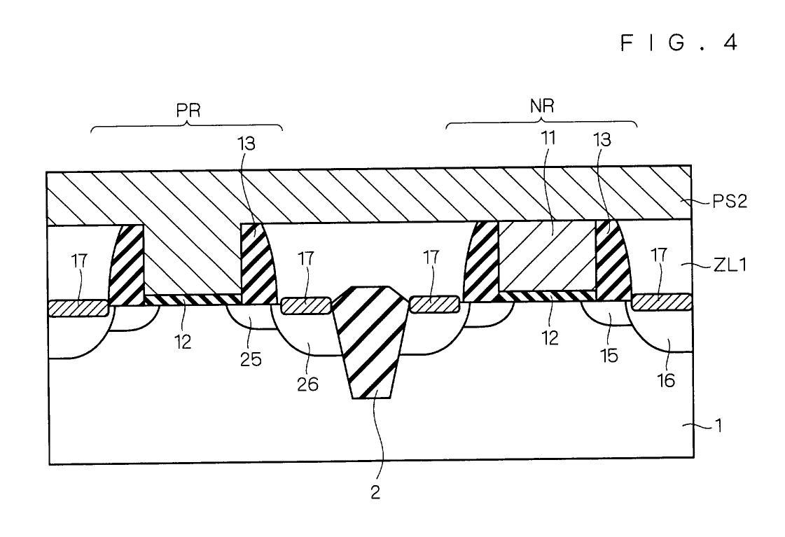

After that, the resist mask RM1 is removed, and in the step of FIG. 4, a doped polysilicon layer PS2 containing boron is formed entirely on the interlayer insulating film ZL1 by the CVD method in a material gas including a compound containing boron such as BCl₃ (boron trichloride), to fill the opening left after removing the gate electrode 11 in the region PR with the doped polysilicon layer PS2.

In the doped polysilicon layer PS2, boron atoms are uniformly distributed with high activation rate (as compared with a case where the impurity of almost equal concentration is ion-implanted), and this layer is referred to as a P-type doped polysilicon layer in some case hereafter. Further, the doped polysilicon layer PS2 contains the P-type impurity in a concentration range of 5×10¹⁹ to 5×10²⁰/cm³.

Further, the depth of the opening left after removing the gate electrode 11 in the region PR is about 200 nm, and the thickness of the doped polysilicon layer PS2 may be almost the same as the depth of the opening or about half the gate length of the longest one out of the gate electrodes in a plurality of P-channel MOS transistors formed on the silicon substrate 1.

Next, by removing the doped polysilicon layer PS2 on the interlayer insulating film ZL1 through etchback or CMP to expose the interlayer insulating film ZL1, a P-channel MOS transistor P1 having the gate electrode 21 containing boron is formed in the region PR and an N-channel MOS transistor N1 having the gate electrode 11 containing phosphorus is formed in the region NR.

Further, a cobalt silicide layer 18 is selectively formed on the gate electrodes 11 and 21 and an interlayer insulating film ZL2 is formed on the interlayer insulating film ZL1 if necessary, to fully cover the P-channel MOS transistor P1 and the N-channel MOS transistor N1. After that, a contact hole CH1 which penetrates the interlayer insulating films ZL1 and ZL2 to reach the silicide layer 17 and a contact hole CH2 which penetrates the interlayer insulating film ZL2 to reach the silicide layer 18 are formed.

Then, a conductor such as tungsten is buried inside the contact holes CH1 and CH2, to form contact plugs CP1 and CP2. Further, the contact plugs CP1 and CP2 are electrically connected with aluminum wire or the like, to achieve a desired CMOS transistor 1000.

Furthermore, in forming the contact plugs CP1 and CP2, there may be a case where the inside of the contact holes CH1 and CH2 are covered with a barrier metal such as TiN and tungsten or the like is buried thereafter.

<A-2. Action and Effect>

According to the above-discussed method of manufacturing a semiconductor device in accordance with the first preferred embodiment, since the N-channel MOS transistor N1 has the gate electrode 11 containing the N-type impurity and the P-channel MOS transistor P1 has the gate electrode 21 containing the P-type impurity, it is possible to achieve a CMOS transistor of dual-gate structure in which these two MOS transistors are each of SC structure and it becomes easier to manufacture a MOS transistor which can respond to miniaturization.

Further, by introducing boron through the CVD method in forming the gate electrode 21, it is not only possible to suppress depletion of the gate electrode since the boron atoms are uniformly distributed with high activation rate in the gate electrode 21, but also possible to prevent penetration of boron from the gate electrode to the silicon substrate 1, which is caused by thermal diffusion resulting from the high-temperature heat treatment, since the activation annealing is not needed after introducing the boron.

Therefore, it is possible to provide a CMOS transistor capable of avoiding deterioration in capability of the P-channel MOS transistor to drive the drain currents, which is caused by depletion of the gate electrode, and preventing variation in threshold values of the P-channel MOS transistor, which is caused by penetration of born.

<A-3. Variations>

Though the case where the gate electrode 11 in the region PR is removed and then the doped polysilicon layer PS2 containing boron is formed with the gate insulating film 12 left without removing is shown referring to FIG. 3 in the above first preferred embodiment of the present invention, there may be a case where a new gate insulating film is formed after removing the gate insulating film 12.

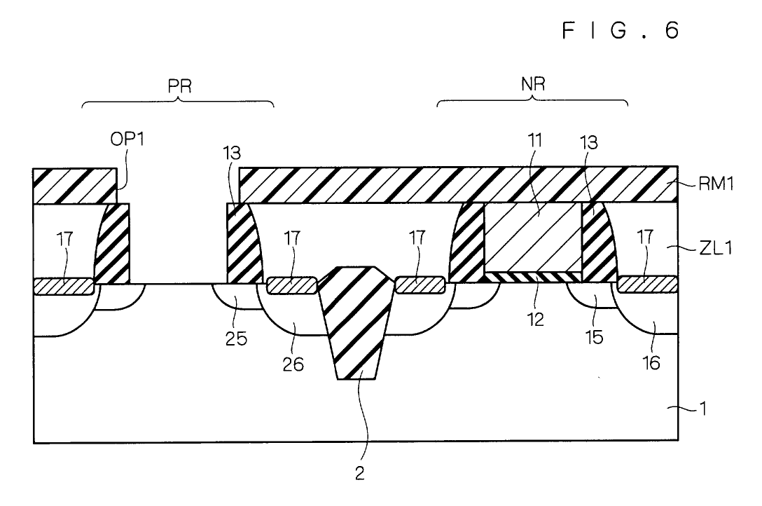

Specifically, after removing the gate electrode 11 in the region PR through the step of FIG. 3, the gate insulating film 12 formed of silicon oxide film is removed with hydrofluoric acid (HF) or the like as shown in FIG. 6. Further, the sidewall spacers 13, which are formed of silicon nitride film, are not affected in removing the gate insulating film 12.

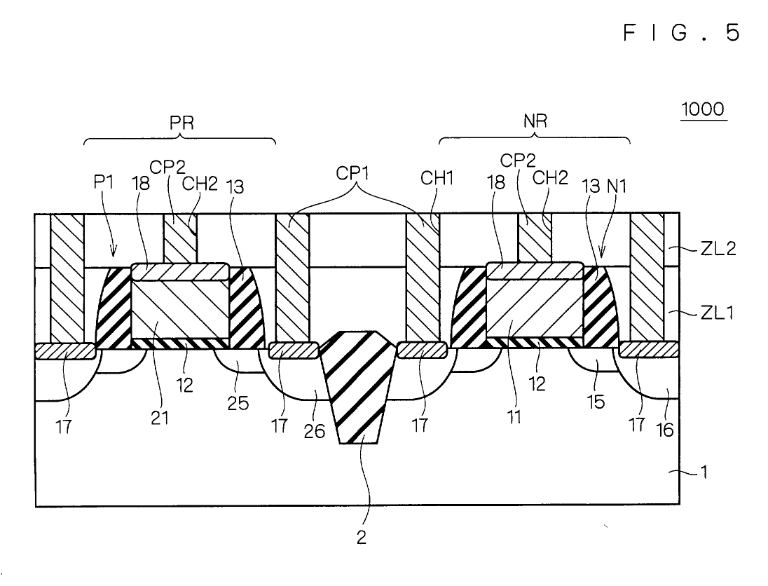

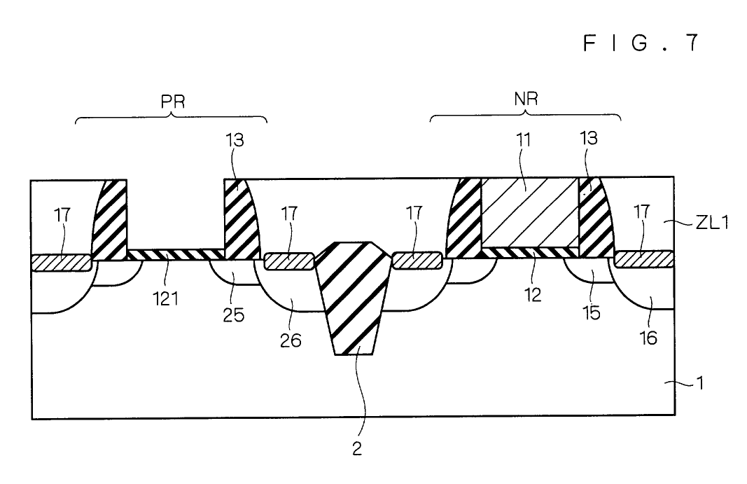

After that, the resist mask RM1 is removed and a thermal oxidation is performed in the step of FIG. 7, to form a gate insulating film 121 of silicon oxide film at a bottom surface of the opening surrounded by the sidewall spacers 13. After this step, through the steps of FIGS. 4 and 5, it is possible to provide a CMOS transistor with higher reliability for the gate insulating film of the P-channel MOS transistor.

Alternatively, instead of performing the thermal oxidation in the step of FIG. 7, a high-dielectric film such as Ta₂O₅ may be formed as a gate insulating film entirely on the silicon substrate 1 by the sputtering method or the CVD method,. In this case, the high-dielectric film is so formed as to cover the inside wall of the opening surrounded by the sidewall spacers 13.

By forming the gate insulating film of a material with high dielectric constant, it is possible to achieve an advantage that the current control capability of the gate electrode does not deteriorate even if the film becomes thicker and the leakage current decreases by an increase in film thickness.

Further, though most of high-dielectric materials are vulnerable to heat, the high-dielectric materials can be used since no high-temperature heat treatment such as annealing is performed in forming the source/drain layers after forming the gate electrode 21 in the manufacturing method of the first preferred embodiment.

Furthermore, also in the process for forming the N-channel MOS transistor N1, like the process for forming the P-channel MOS transistor P1, there may be a case where a dummy gate electrode is once formed and then the gate insulating film as well as the gate electrode are removed and a new gate insulating film is formed of a high-dielectric material.

<B. The Second Preferred Embodiment>

<B-1. Manufacturing Method>

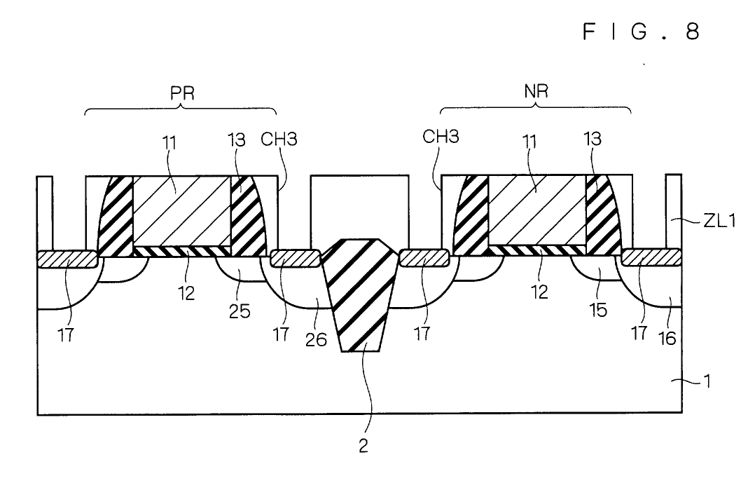

A method of manufacturing a semiconductor device in accordance with the second preferred embodiment of the present invention will be discussed, referring to the cross sections of FIGS. 8 to 12 showing the manufacturing process step by step. Constituent elements identical to those in the first preferred embodiment discussed referring to FIGS. 1 to 5 are represented by the same reference signs and duplicate discussion will be omitted.

After the steps of FIGS. 1 and 2, first, in the step of FIG. 8, the interlayer insulating film ZL1 is so formed as to have a thickness of about 1500 nm on the main surface of the silicon substrate 1, to fully cover the first and second gate multi-layered structures and the sidewall spacers 13. After that, the interlayer insulating film ZL1 is polished by CMP (Chemical Mechanical Polishing) and the whole TEOS oxide film 14 and the upper end portions of the sidewall spacers 13 are also polished, to expose the uppermost surface of the gate electrode 11.

Further, a contact hole CH3 which penetrates the interlayer insulating film ZL1 to reach the silicide layer 17 is formed.

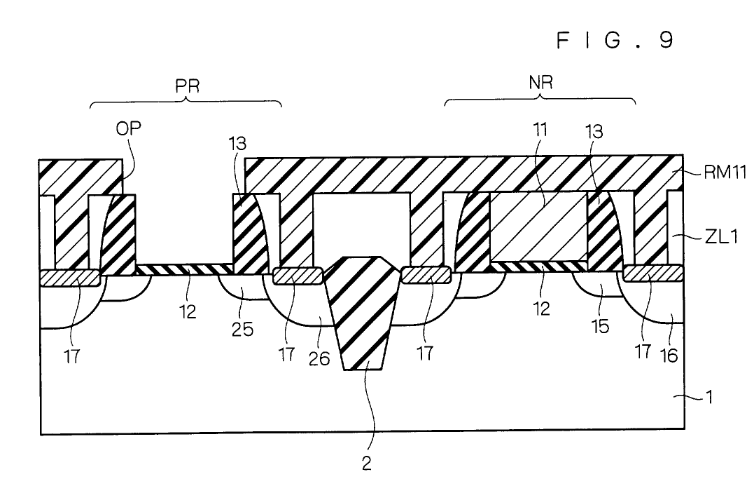

Next, in the step of FIG. 9, the upper portion of the gate electrode 11 in the region PR becomes the opening OP, and using a resist mask RM11 which is so patterned as to cover a portion other than the opening OP, the gate electrode 11 (dummy gate electrode) in the region PR is removed by wet etching with a mixture of hydrofluoric acid (HF) and nitric acid (HNO₃) or a potassium hydroxide (KOH) solution.

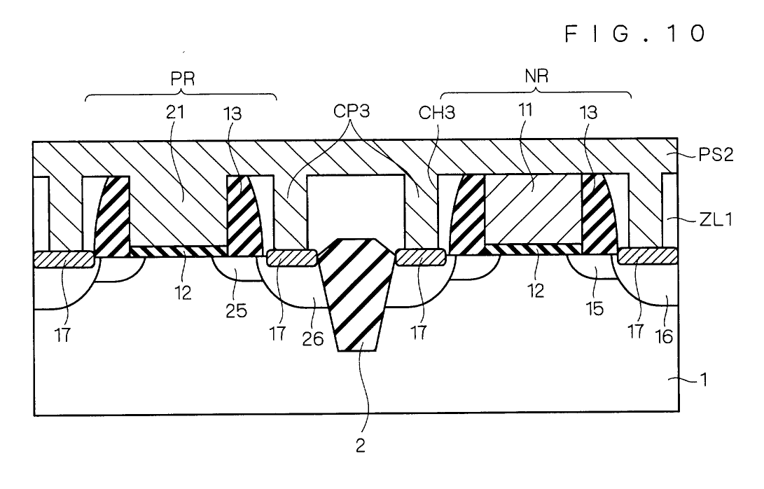

After that, the resist mask RM11 is removed, and in the step of FIG. 10, the doped polysilicon layer PS2 containing boron is formed by the CVD method in a material gas including a compound containing boron such as BCl₃ (boron trichloride). In the doped polysilicon layer PS2, boron atoms are uniformly distributed with high activation rate (as compared with a case where the impurity of almost equal concentration is ion-implanted).

Through the step, the opening left after removing the gate electrode 11 in the region PR is filled with the doped polysilicon layer PS2 and the contact hole CH3 is also filled with the doped polysilicon layer PS2, to form the gate electrode 21 and a contact plug CP3.

As a result, the P-channel MOS transistor P1 having the gate electrode 21 containing boron is formed in the region PR and the N-channel MOS transistor N1 having the gate electrode 11 containing phosphorus is formed in the region NR.

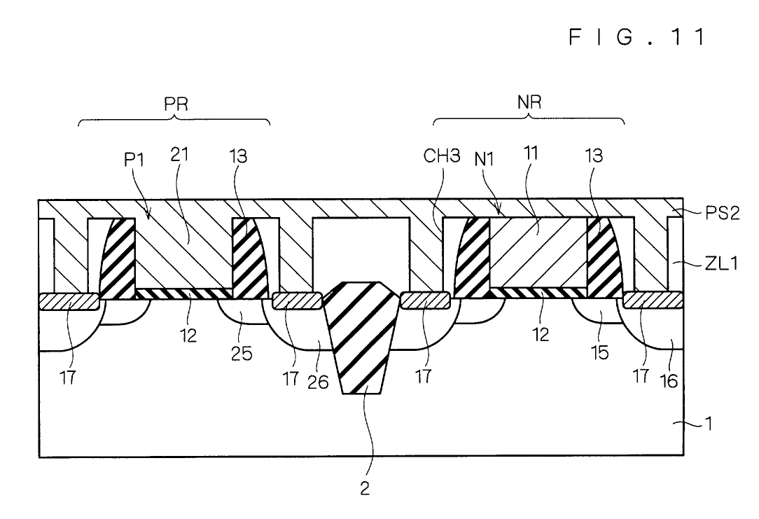

Next, in the step of FIG. 11, the doped polysilicon layer PS2 on the interlayer insulating film ZL1 is removed through etchback or CMP until its thickness becomes a predetermined thickness.

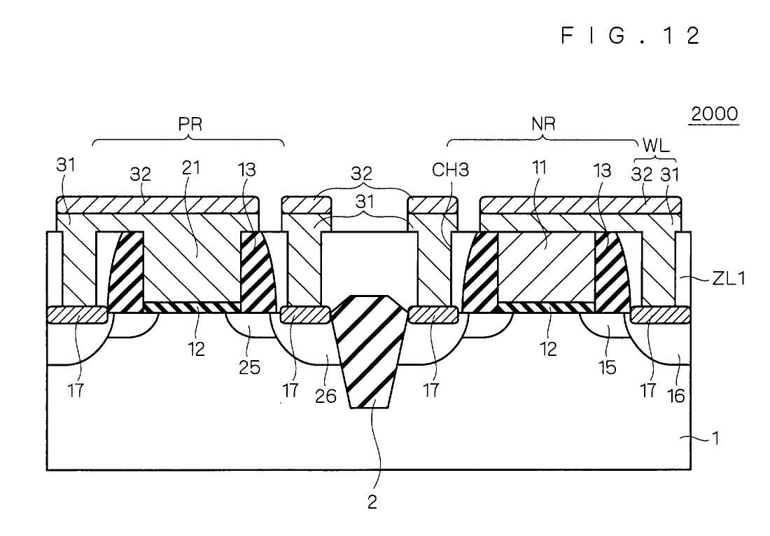

Next, in the step of FIG. 12, the remaining polysilicon layer PS2 is patterned to form polysilicon wires 31, and then in order to lower the resistance of the polysilicon wires 31, a refractory metal layer such as a cobalt layer is formed on the polysilicon wires 31 and a heat treatment is performed on the refractory metal layer. With this treatment, a silicide reaction is selectively made between silicon and cobalt to form a silicide layer 32, and a CMOS transistor 2000 is achieved, which has a wire layer WL consisting of the polysilicon layer 31 and the silicide layer 32, as shown in FIG. 12.

In forming the wire layer WL, a patterning is so performed as to, for example, electrically connect the gate electrode 21 and one of the pair of source/drain layers 26 in the region PR and electrically connect the gate electrode 11 and one of the pair of source/drain layers 16 in the region NR. Naturally, the wiring pattern may be optionally determined, and specifically, there may be cases where the gate electrode is not connected to the source/drain layer and where the gate electrodes 11 and 21 are electrically connected to each other with the wire layer WL.

Further, the gate electrode 11 of the N-channel MOS transistor N1 is a polysilicon containing the N-type impurity and forms a PN junction when comes into contact with the polysilicon layer 31 of the wire layer WL containing the P-type impurity.

Since the voltage applied to the gate electrode 11 of the N-channel MOS transistor N1, however, is usually positive and a forward bias for the PN junction, the junction is not a problem.

<B-2. Action and Effect>

The above-discussed method of manufacturing a semiconductor device in accordance with the second preferred embodiment produces the same effect as discussed in the first preferred embodiment and further eliminates necessity of forming any contact portion for electrically connecting the gate electrodes 11 and 21 and the wire layer WL.

Further, in forming the contact portion for electrically connecting the source/drain layers 16 and 26 and the wire layer WL, it is not necessary to form and remove a conductor layer to fill the contact hole CH3 and the structure of the device is simplified.

Furthermore, the gate electrode 11 of the N-channel MOS transistor N1 and the polysilicon layer 31 which is a constitute of the wire layer WL form a PN junction, as discussed earlier, and the presence of the PN junction produces the following effect.

Specifically, when a potential of the gate electrode 11 becomes lower then that of the source layer, for example, the potential of the source layer is 0 V and that of the gate electrode 11 is −2 V, this is a reverse bias for the PN junction and a voltage of 2 V is not applied to the gate insulating film 12. It is therefore possible to prevent a large amount of leakage currents from being generated between the end portion of the source layer and the gate electrode 11 through the gate insulating film 12.

Further, though Japanese Patent Application Laid Open Gazette No. 10-125799 discloses a structure in which only a gate electrode of an N-channel MOS transistor has a double-layer structure consisting a P-type polysilicon layer and an N-type polysilicon layer, this structure has a diffusion preventive film of TiN between the P-type polysilicon layer and the N-type polysilicon layer and is different from the structure of the CMOS transistor 2000 shown in FIG. 12.

Such a difference in structure is caused by the manufacturing method. Specifically, in the manufacturing method shown in Japanese Patent Application Laid Open Gazette No. 10-125799, since a heat treatment to form a source/drain layer is performed after forming the double-layer structure consisting of the P-type polysilicon layer and the N-type polysilicon layer, the diffusion preventive film for preventing mutual diffusion of impurities in the gate electrode to suppress variation in threshold values of the MOS transistor is required. On the other hand, in the manufacturing method of the present invention, since the polysilicon layer 31 of the wire layer WL, containing the P-type impurity, is formed on the gate electrode 11 containing the N-type impurity after forming the source/drain layers, there occurs little mutual diffusion of impurities between the polysilicon layer 31 and the gate electrode 11.

Further, in the manufacturing method shown in Japanese Patent Application Laid Open Gazette No. 10-125799, since the N-type polysilicon layer is formed by ion-implanting the N-type impurity below the gate electrode of the N-channel MOS transistor, the N-type impurity is not uniformly distributed and it is therefore not possible to prevent depletion of the gate electrode.

<C. The Third Preferred Embodiment>

<C-1. Manufacturing Method>

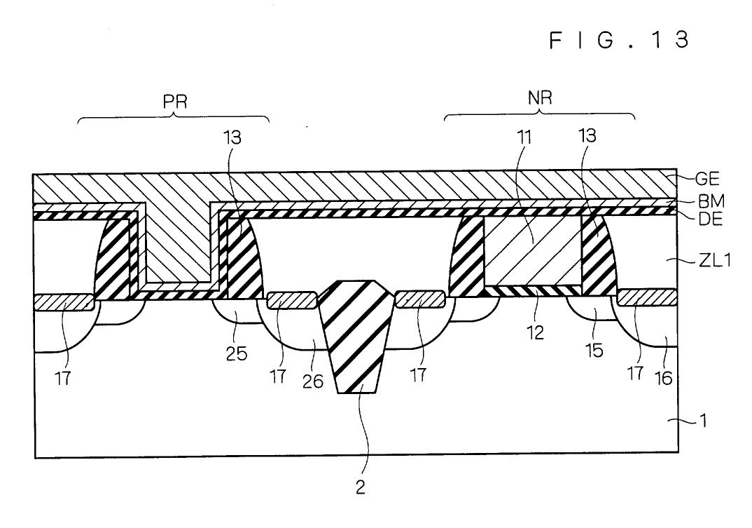

A method of manufacturing a semiconductor device in accordance with the third preferred embodiment of the present invention will be discussed, referring to the cross sections of FIGS. 13 to 15 showing the manufacturing process step by step. Constituent elements identical to those in the first preferred embodiment discussed referring to FIGS. 1 to 5 are represented by the same reference signs and duplicate discussion will be omitted.

After the steps of FIGS. 1 and 2, first, in the step of FIG. 13, the interlayer insulating film ZL1 is so formed as to have a thickness of about 1500 nm on the main surface of the silicon substrate 1, to fully cover the first and second gate multi-layered structures and the sidewall spacers 13.

After that, the interlayer insulating film ZL1 is polished by CMP (Chemical Mechanical Polishing) and the whole TEOS oxide film 14 and the upper end portions of the sidewall spacers 13 are also polished, to expose the uppermost surface of the gate electrode 11.

Next, the upper portion of the gate electrode 11 in the region PR becomes an opening, and using a resist mask (not shown) which is so patterned as to cover a portion other than the opening, the gate electrode 11 (dummy gate electrode) in the region PR is removed by wet etching with a potassium hydroxide (KOH) solution or aqueous ammonia.

Further, the gate insulating film 12 formed of silicon oxide film is removed with hydrofluoric acid (HF) or the like. Furthermore, the sidewall spacers 13, which are formed of silicon nitride film, are not affected in removing the gate insulating film 12. In this case, if the interlayer insulating film ZL1 is formed of silicon nitride film, it is possible to prevent the interlayer insulating film ZL1 from being removed even if the opening OP of the resist mask RM1 extends over the interlayer insulating film ZL1 in removing the gate insulating film 12.

After that, the resist mask is removed and a high-dielectric film DE such as Ta₂2O₅ is formed entirely on the silicon substrate 1 by the sputtering method. Further, a barrier metal layer BM of TiN or the like is formed on the high-dielectric film DE by the sputtering method. Furthermore, the high-dielectric film DE may be formed of HfO₂.

In this case, the high-dielectric film DE has a thickness of, for example, about 10 nm (100 Å) and the barrier metal layer BM has a thickness of, for example, about 10 nm (100 Å), and these films are so formed as to cover the inner wall of the opening left after removing the gate electrode 11 in the region PR.

After that, a conductor layer GE is formed of a metal such as tungsten entirely on th silicon substrate 1 by the sputtering method. In this case, the conductor layer GE has a thickness of, for example, about 500 nm (5000 Å) and can fully fill the opening left after removing the gate electrode 11 in the region PR. Further, the conductor layer GE may be formed of aluminum (AL).

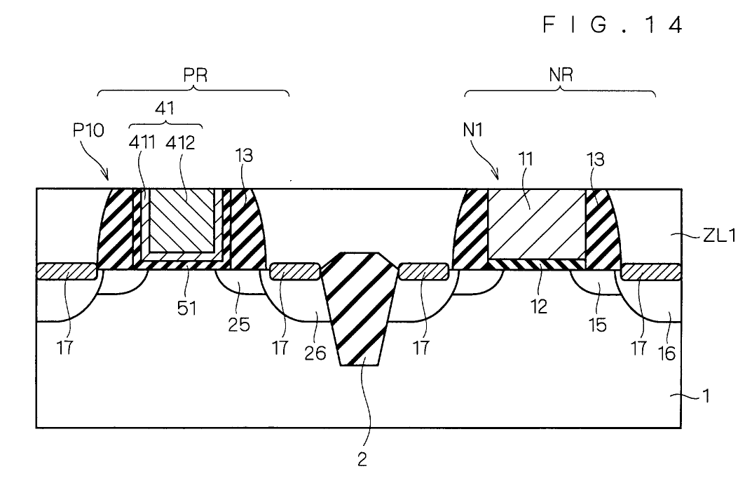

Next, in the step of FIG. 14, by removing the conductor layer GE, the barrier metal layer BM and the high-dielectric film DE on the interlayer insulating film ZL1 through etchback or CMP to expose the interlayer insulating film ZL1, a P-channel MOS transistor P10 having a gate electrode 41 consisting of a barrier metal layer 411 and a gate metal layer 412 is formed in the region PR and the N-channel MOS transistor N1 having the gate electrode 11 containing phosphorus is formed in the region NR.

Further, since the high-dielectric film DE provided below the gate electrode 41, which becomes a gate insulating film 51, has a high dielectric constant, there arises an advantage that the current control capability of the gate electrode does not deteriorate even if the film becomes thicker and the leakage current decreases by an increase in film thickness.

Furthermore, though most of high-dielectric materials are vulnerable to heat, the high-dielectric materials can be used since no high-temperature heat treatment such as annealing is not performed in forming the source/drain layers after forming the gate electrode 41 in the manufacturing method of the third preferred embodiment.

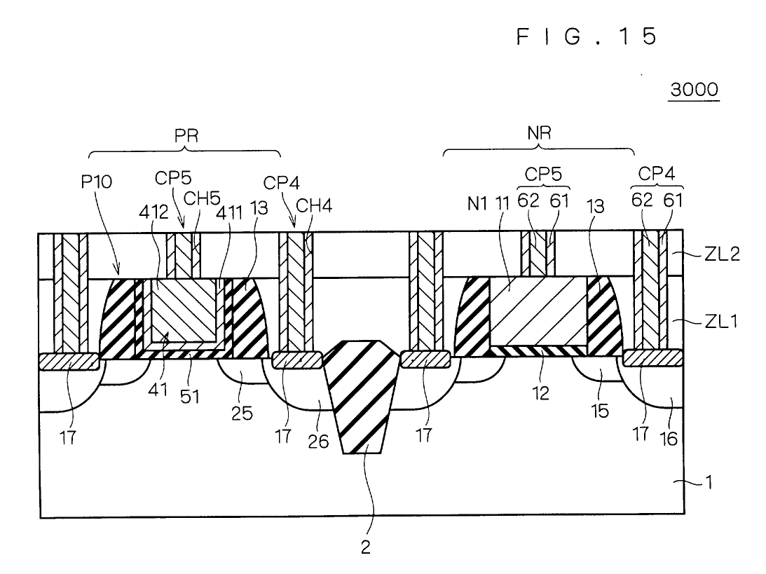

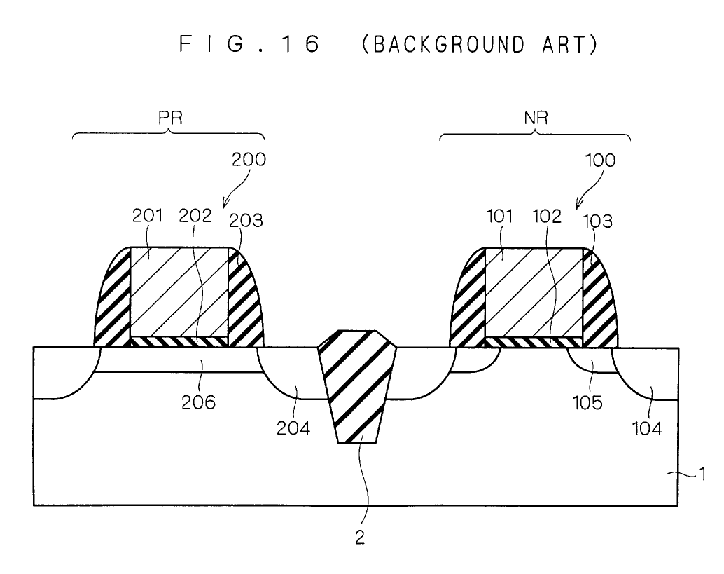

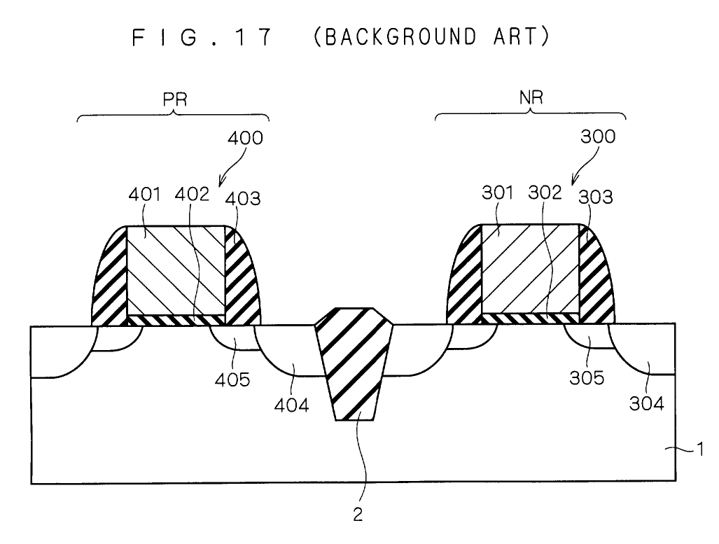

Next, if necessary, as shown in the step of FIG. 15, the interlayer insulating film ZL2 is formed on the interlayer insulating film ZL1, fully cover the P-channel MOS transistor P10 and the N-channel MOS transistor N1. After that, a contact hole CH4 which penetrates the interlayer insulating films ZL1 and ZL2 to reach the silicide layer 17 and a contact hole CH5 which penetrates the interlayer insulating film ZL2 to reach the gate metal layer 412 are formed.

Then, after covering the insides of the contact holes CH4 and CH5 with a barrier metal layer 61 of TiN or the like, a conductor layer 62 of tungsten or the like is buried therein to form contact plugs CP4 and CP5. In this case, the barrier metal layer 61 and the conductor layer 62 are formed by the sputtering method, and when the diameter of the contact holes CH4 and CH5 is 500 nm (5000 Å), the thickness of the barrier metal layer 61 should be about 15 nm (150 Å) and that of the conductor layer 62 should be 500 nm (5000 Å).

After this, the contact plugs CP4 and CP5 are electrically connected with an aluminum wire or the like, to achieve a desired CMOS transistor 3000.

<C-2. Action and Effect>

According to the above-discussed method of manufacturing a semiconductor device in accordance with the third preferred embodiment, since the gate in the P-channel MOS transistor P10 is formed of a metal, it is possible to completely avoid depletion of the gate electrode. Further, it is also possible to reduce the gate resistance.

Since no high-temperature heat treatment is performed after forming the gate electrode 41, it is possible to use high-dielectric materials and achieve a CMOS transistor capable of reducing the leakage currents in the gate electrode.

Further, the N-channel MOS transistor N1 has a SC structure using a doped polysilicon gate electrode containing the N-type impurity (phosphorus), and the depletion of the gate electrode is hard to occur therein.

Furthermore, though the case where tungsten is used for the gate electrode 41 in the P-channel MOS transistor P10 is shown in the third preferred embodiment, there is a possibility that the P-channel MOS transistor P10 may be formed in a SC structure, depending on the work function of the metal used therefor.

Specifically, if a metal whose work function is over 4.7 V is used as a material for the gate, there is a possibility of achieving a MOS transistor of SC structure. When tungsten with work function of 4.55 V is used, the P-channel MOS transistor P10 is formed only in a BC structure. When platinum (Pt) with work function of 5.65 V, rhodium (Rh) with work function of 4.98 V or molybdenum (Mo) with work function of 4.80 V is used, the P-channel MOS transistor P10 can be formed in a SC structure. Then, since both the N-channel MOS transistor N1 and the P-channel MOS transistor P10 each have a SC structure, this case has an advantage in miniaturization.

Further, though the N-channel MOS transistor N1 may have a structure using a metal gate electrode, like the P-channel MOS transistor P10, there is a possibility in this case that the N-channel MOS transistor N1 can not be formed in a SC structure even if the same metal as used for the gate electrode 41 is used. In such a case, a different metal should be used.

Furthermore, since the gate electrode 41 consists of the barrier metal layer 411 and the gate metal layer 412, it is possible to prevent penetration of metallic atom from the gate metal layer 412 to the silicon substrate 1.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
an N-channel MOS transistor provided on a semiconductor substrate; and
a P-channel MOS transistor provided on said semiconductor substrate,
wherein said N-channel MOS transistor has a first gate insulating film selectively provided on a surface of said semiconductor substrate; and
a first gate electrode provided on said first gate insulating film,
said P-channel MOS transistor has a second gate insulating film selectively provided on said surface of said semiconductor substrate; and
a second gate electrode provided on said second gate insulating film,
said first gate electrode is formed of a first doped polysilicon layer containing an N-type impurity therein, and
said second gate electrode is formed of a second doped polysilicon layer containing a P-type impurity therein.

2. The semiconductor device according to claim 1, further comprising:
a wire layer so provided as to come into contact with at least upper end surfaces of said first and second gate electrodes,
wherein said wire layer has a third doped polysilicon layer containing a P-type impurity therein and is provided so that said third doped polysilicon layer comes into contact with said upper end surfaces of said first and second gate electrodes.

3. The semiconductor device according to claim 2, wherein
said N-channel MOS transistor and said P-channel MOS transistor comprise a pair of N-type source/drain layers and a pair of P-type source/drain layers provided in said surface of said semiconductor substrate positioned in external portions of side surfaces of said first gate electrode and said second gate electrode, respectively, and
said third doped polysilicon layer is electrically connected to either one of said pair of N-type source/drain layers or either one of said pair of P-type source/drain layers through a contact hole.

4. The semiconductor device according to claim 2, wherein
said wire layer further has a silicide layer provided on said third doped polysilicon layer.

5. The semiconductor device according to claim 1, wherein
at least said second gate insulating film is formed of a high-dielectric film.

6. The semiconductor device according to claim 5, wherein
said high-dielectric film is Ta₂O₅ or HfO₂.

7. A semiconductor device comprising:
an N-channel MOS transistor provided on a semiconductor substrate; and
a P-channel MOS transistor provided on said semiconductor substrate,
wherein said N-channel MOS transistor has a first gate insulating film selectively provided on a surface of said semiconductor substrate; and
a first gate electrode provided on said first gate insulating film,
said P-channel MOS transistor has a second gate insulating film selectively provided on said surface of said semiconductor substrate; and
a second gate electrode provided on said second gate insulating film,
said first gate electrode is formed of a first doped polysilicon layer containing an N-type impurity therein, and
said second gate electrode is formed of at least one metal layer.

8. The semiconductor device according to claim 7, wherein
said at least one metal layer has
a barrier metal layer so provided as to come into contact with said second gate insulating film; and
a gate metal layer provided on said barrier metal layer.

9. The semiconductor device according to claim 7, wherein
at least said second gate insulating film is formed of a high-dielectric film.

10. The semiconductor device according to claim 9, wherein
said high-dielectric film is Ta₂O₅ or HfO₂.
